(19) United States
(12) Patent Application Publication
(10) Pub. No.: US 2018/0080138 A1
(43) Pub. Date: Mar. 22, 2018

(54) PROCESSES FOR REDUCING SURFACE CONCENTRATION OF DYES IN ANODIC OXIDES

(71) Applicant: Apple Inc., Cupertino, CA (US)

(72) Inventors: James A. CURRAN, Morgan Hill, CA (US); Kevin B. MICKLEWRIGHT, Cupertino, CA (US); Karin H. RASMUSSEN, Cupertino, CA (US)

(21) Appl. No.: 15/410,564

(22) Filed: Jan. 19, 2017

Related U.S. Application Data
(60) Provisional application No. 62/398,441, filed on Sep. 22, 2016.

(51) Int. Cl. C25D 11/24; H05K 5/04; H05K 5/02

(52) U.S. Cl. CPC C25D 11/243; H05K 5/0243; H05K 5/04

(57) ABSTRACT

Dyed anodic oxides having modified dye concentration profiles, and processes for forming the same, are described. The modified dye concentration profiles can be characterized as having a peak of dye concentration beyond at least a specified distance from an outer surface of an anodic oxide. The modified dyed anodic oxides less prone to discoloration, color fading and other cosmetic defects compared to conventionally dyed anodic oxides. The dyed anodic oxides are well suited for implementation on metal surfaces of consumer products, such as consumer electronic products.

### CROSS-REFERENCE TO RELATED APPLICATION

This application claims the benefit of priority under 35 U.S.C. § 119(e) to U.S. Provisional Application No. 62/398,441, entitled “PROCESSES FOR REDUCING SURFACE CONCENTRATION OF DYES IN ANODIC OXIDES,” filed on Sep. 22, 2016, which is incorporated by reference herein in its entirety.

### FIELD

The described embodiments relate to anodic films. The anodic films can be characterized as having a dye concentration distribution that reduces the occurrence of cosmetic defects.

### BACKGROUND

Aluminum products are often anodized to increase corrosion resistance and to allow for coloring of the product. The coloring process generally involves depositing a dye within the porous structure of the anodic film. Dyed anodic films typically exhibit highest dye concentrations at their outermost surface, with dye concentration falling dramatically as a function of depth from the surface. Such dye distributions are disadvantageous in certain finishing processes. In particular, the outermost portions are removed during these processes, thereby removing a large portion of the dye and leaving a color-faded or unevenly colored anodic film. Furthermore, outer surfaces of the anodic films can wear away during the service lifetime of the product, leading to cosmetic defects. What are needed therefore are improved coloring techniques for anodic films.

### SUMMARY

This paper describes various embodiments that relate to anodic films. In particular embodiments, anodic films have a dye concentration distribution that makes the anodic films less prone to cosmetic defects.

According to one embodiment, a part is described. The part includes an anodic film having a dye deposited therein. A peak of concentration of the dye is at least 200 nanometers from an outer surface of the anodic film.

According to another embodiment, a method of dyeing an anodic film is described. The method includes depositing a dye within pores of the anodic film. The method also includes removing some of the dye from the pores such that a peak of concentration of the dye is at least 200 nanometers from an outer surface of the anodic film.

According to a further embodiment, an electronic device is described. The electronic device includes an aluminum alloy substrate having an anodic film with a dye deposited therein. The anodic film is characterized as having a peak of concentration of the dye that is at least 200 nanometers from an outer surface of the anodic film.

These and other embodiments will be described in detail below.

### BRIEF DESCRIPTION OF THE DRAWINGS

The disclosure will be readily understood by the following detailed description in conjunction with the accompanying drawings, wherein like reference numerals designate like structural elements.

FIG. 1 shows perspective views of devices having metal surfaces that can be treated with the coatings described herein.

FIG. 2A shows a cross-section view of a surface portion of an anodized part after a coloring process.

FIG. 2B shows a graph indicating a dye concentration profile within the anodic film of the part in FIG. 2A.

FIG. 3A shows the part of FIG. 2A after a controlled dye removal process.

FIG. 3B shows a graph indicating a dye concentration profile within the anodic film of the part described in FIG. 2A-3A.

FIG. 4 shows a graph based on secondary ion mass spectroscopy (SIMS) data comparing dye concentration profiles of an anodized substrate before and after a dye removal process.

FIGS. 5A and 5B show flowcharts comparing a process a conventional anodic dyeing process to a modified anodic dyeing process, in accordance with some embodiments.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

Processes to modify the distribution of dye within an anodic film are described. Specifically, a peak of dye concentration is shifted away from an outer surface of the anodic film and towards an underlying substrate. This dye distribution modification is shown to reduce the occurrence of visible defects and to minimize or overcome certain other limitations associated with dyed anodic films. For example, surfaces of the anodic films having the modified dye distributions can be finished (e.g., polished or buffed) with little change in coloration compared to anodic films with conventional dye distributions. Also, the anodic films with the modified dye distributions can be sealed more effectively than anodic films with conventional dye distributions. These and other advantages are described in detail herein.

Methods of modifying the dye distribution can include exposing the anodic film to a solution such that outermost portions of the dye are removed from the anodic film by diffusive action. In some case, a hot aqueous solution is used. The solution temperature and exposure time can be varied to achieve a desired dye distribution. In some embodiments, the solution temperature is maintained substantially below a temperature at which a hydrothermally boehmite formation occurs, thus preventing any significant sealing of the anodic film. The anodic film can then be sealed after the dye removal process is complete.

As described herein, the terms anodic film, anodic oxide, anodic oxide coating, anodic layer, anodic coating, oxide film, oxide layer, oxide coating, etc. can be used interchangeably and can refer to suitable metal oxide materials, unless otherwise specified.

The substrates and coatings described herein are well suited for providing cosmetically appealing consumer products. For example, the dyed anodic films can be used to form durable and cosmetically appealing finishes for housing of computers, portable electronic devices, wearable electronic devices, and electronic device accessories, such as those manufactured by Apple Inc., based in Cupertino, Calif.

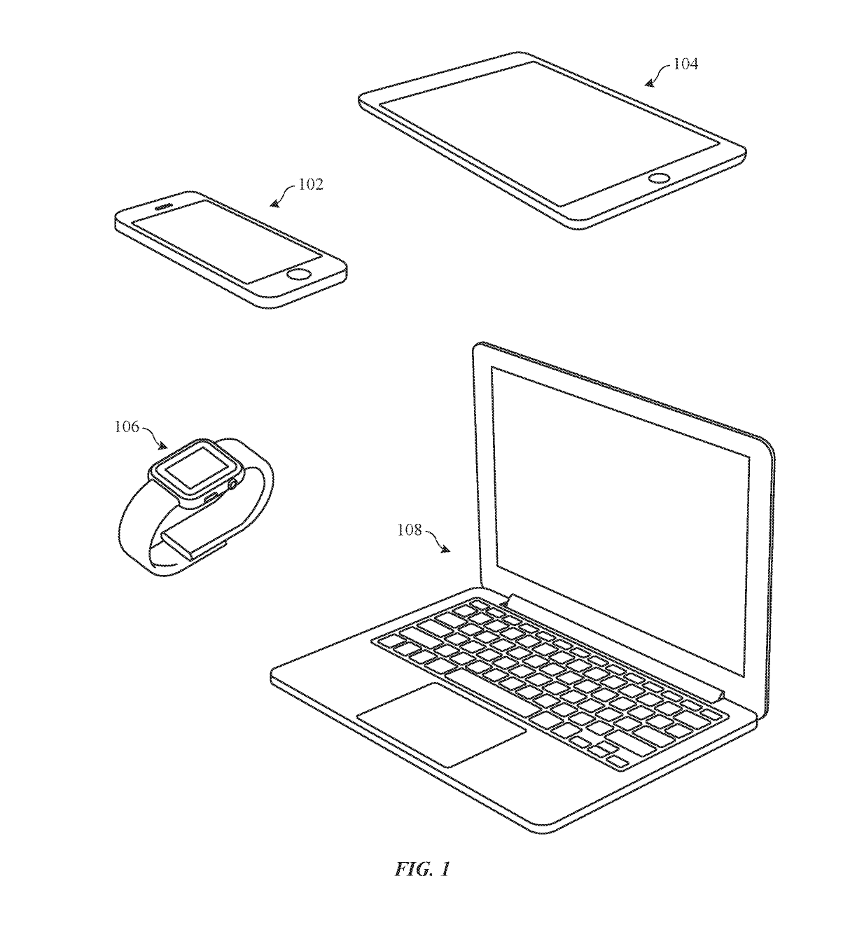

These and other embodiments are discussed below with reference to FIGS. 1-5B. However, those skilled in the art will readily appreciate that the detailed description given herein with respect to these Figures is for explanatory purposes only and should not be construed as limiting.

The methods described herein can be used to form durable and cosmetically appealing coatings for metallic surfaces of consumer devices, such as those shown in FIG. 1. FIG. 1 includes portable phone 102, tablet computer 104, smart watch 106 and portable computer 108, each of which can include enclosures that are made of metal or have metal sections. These metal or metal sections can be composed of aluminum, aluminum alloys, or other suitable anodizable metal. When anodized, a protective anodic film is formed, which can protect the underlying metal substrate from scratches. The anodic film can also be infused with one or more dyes, adding numerous cosmetic options for product lines.

One of the problems associated with colored anodic films is that the dye can leach out of the anodic film during the service lifetime of a product. For example, devices 102, 104, 106 and 108 may be exposed to liquids such as water, oils and corrosive chemicals during use. Watch 106, in particular, is in contact with a person's skin, which may expose watch 106 to sweat and various lotions, such as sunscreens. In addition, watch 106 may be designed for prolonged under-water use and can be expected to be exposed to waters such as tap water, swimming pool water and ocean water—at a variety of pHs and temperatures, and with varying concentrations of chemicals such as chlorides. When the colored anodic films are exposed to such liquids and chemical agents, the dye may leach out and cause devices 102, 104, 106 and 108 to have uneven coloring and cosmetic defects. The processes described herein involve treating colored anodic film such that the anodic films are less inclined to develop these cosmetic defects.

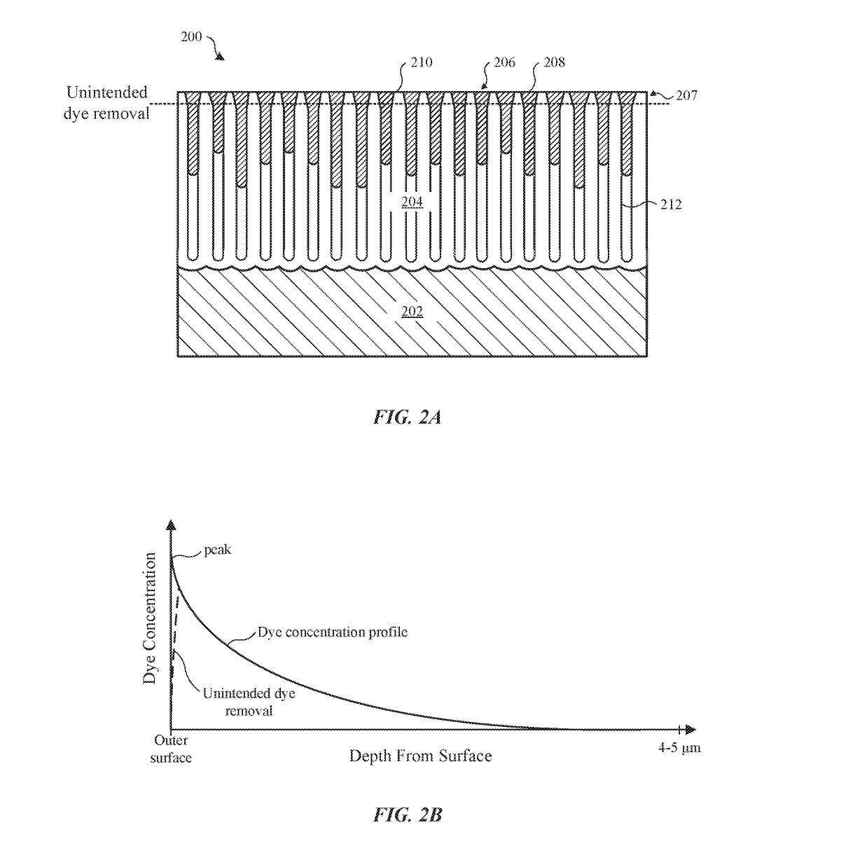

FIG. 2A shows a cross-section view of a surface portion of part 200 after a coloring process. Part 200 includes substrate 202, which can be composed of any suitable anodizable metal. In some cases, substrate 202 is composed of an aluminum alloy. Part 200 also includes anodic film 204 formed from an anodizing process, in which a portion of substrate 202 is converted to a corresponding metal oxide. Thus, surface portion of an aluminum or aluminum alloy substrate 202 is converted to an aluminum oxide anodic film 204. The thickness of anodic film 204 can vary depending on the anodizing process and on application requirements. In some applications for consumer electronic products, the thickness of anodic film 204 ranges from about 5 micrometers to about 50 micrometers.

As shown, anodic film 204 has a porous structure that includes a number of elongated pores 206 defined by pore walls 212. The size of pores 206 depends upon the anodizing process conditions. In some applications, a Type II anodizing process (per Mil-A-8625 specifications) is used, which involves anodizing in a sulfuric acid-containing electrolyte, and which generally results in anodic film 204 having relatively small pores 206 (e.g., having diameters ranging between about 5 nm to 100 nm). This small pore 206 size is associated with an optically transparent anodic film 204, which can be beneficial in cases where precisely controlled coloring of anodic film 204 is desired. These pores 206 act as reservoirs for dye 208 to reside.

In some embodiments, the coloring process involves immersing part 200 in a solution or gel that includes dye 208. Dye 208 can be composed of any suitable colorant, such as an organic-based dye, inorganic-based dye, or suitable combinations thereof. Many anodic dyes include a combination of organic and inorganic species. For example, many dyes include chromophores, which can include conjugated and aromatic organic moieties. Some dyes include ionic species, such as Cu²⁺ within their colorants, but may also include additives that include compounds of sulfur, chlorine, fluorine or phosphates. In some cases, more than one type of dye or colorant is used in order to achieve a specific color. For example, one or more metal materials can be deposited within the terminuses of pores 206 (i.e., near substrate 202) in addition to a dye. While in solution or gel, dye 208 diffuses within pores 206, becoming progressively filled to greater concentrations at greater depths. In some cases, successive dye operations are used in order to achieve a particular color or color intensity.

Once within pores 206, dye 208 adsorbed to pore walls 212, thereby causing the dye 208 to remain in pores 206 after part 200 is removed from the solution. Dye 208 can offer a very wide spectrum of colors to part 200, by adjusting the composition of the dye solution (concentration of colorants, and pH), and by adjusting the time and temperature of the dye solution. By maintaining a constant dye solution composition, pH and temperature, time may be used to precisely fine-tune color to within ΔE* of less than one (per CIELAB color space models) of a given color target during production.

As shown, dye 208 is predominately concentrated at outer portion 207 of anodic film 204 nearest to outer surface 210. This is also illustrated in FIG. 2B, which shows a graph indicating a concentration profile of dye 208 within anodic film 204 as a function of depth (to about 4-5 micrometers) from outer surface 210. The dye concentration profile indicates the dye distribution after a coloring process approximates an exponential function, with a significant percentage of the dye concentrated at the outer portion of the anodic film. That is, the dye concentration profile is characterized as having a peak dye concentration at or near the outer surface. In some cases, the outermost half micrometer of anodic film 204 can contain as much as 50% of dye 208 content.

Although not necessarily problematic in all situations, this type of dye concentration profile can be problematic under certain circumstances. One such circumstance can be where subsequent surface finishing (such as lapping or polishing) is applied to outer surface 210 of anodic film 204. These finishing operations may remove hundreds of nanometers to a few micrometers of anodic film 204 (starting at outer surface 210). Hence, very large color shifts may be observed even when only a small depth of material is removed. Furthermore, it may be difficult to precisely and uniformly remove the anodic film material, especially if part 200 includes curved surfaces. Thus, a finishing process can cause uneven removal of dye 208 from anodic film 204, resulting in inconsistent coloring and cosmetic defects. Having the color strongly determined by outer portion 207 is then undesirable because even very limited material removal results in significant color shifts.

A further circumstance where peak dye concentration at or near outer surface 210 may be problematic is when dye 208 includes components that can result in in-service cosmetic defects. Dyes that include ions (e.g., Cu²⁺), or additives that include compounds of chlorine, fluorine and phosphates, can be detrimental to local hydrothermal seal quality and/or can enhance local erosion or corrosion of substrate 202 upon exposure to certain environments such as alkaline water or sweat. If such dyes are used to achieve intense or dark colors, they can become highly concentrated in outer portion 207 of anodic film 204. Even if a critical threshold for concentration is exceeded only very locally (e.g., tens or hundreds of nanometers of from outer surface 210), the resulting localized erosion or corrosion can result in severe cosmetic defects such as iridescent blooms against dark surfaces.

A third circumstance where the peak dye concentration at or near outer surface 210 may be detrimental relates to weathering-induced color change. In particular, if dye 208 includes chromophores, exposure to light and other environmental factors can degrading the chromophores and change the color of anodic film 204. Having the dye concentrated in outer portion 207, where light intensity, temperature and other exposure factors are strongest is thus disadvantageous for these types of dye compounds.

For at least the reasons set forth above, uncontrolled removal of dye 208 from outer portion 207 can have dramatic and detrimental effects on the cosmetic quality of part 200. One strategy to address this issue involves modifying the dyeing process itself by, for example, forcing dye 208 deeper within anodic film 204. However, these attempts to promote deeper dye penetration have not shown measurable change to the shape of the dye concentration profile of FIG. 2B. For example, electrophoresis techniques, where an electric potential is applied to the dye solution in an attempt to force ionic species within the dye toward the substrate, have not proven to substantially change the dye concentration profile. Neither have methods such as pressure infiltration or sonication (i.e., applying ultrasonics). The ineffectiveness of these methods are an indication that diffusion control is not the main factor limiting dye uptake or in setting the dye concentration profile.

It is believed that a major factor involved in dye up-take relates to the porous structure of anodic film 204. In particular, pore walls 212 at outer portion 207 of anodic film 204 tend to thin and become more porous as a consequence of the anodizing process. More particularly, as the anodizing process proceeds, pore walls 212 are inevitably most heavily etched at their outer extremities. This is because outer portion 207 of anodic film 204 is the first material to be formed during the anodizing process, and hence experiences the longest exposure to the anodizing solution (which must necessarily be a solution in which the oxide material is soluble if a porous anodic film is to be formed). The more porous outer portion 207 of anodic film 204 has more surface area for dye 208 to adsorb onto. Thus, it is believe this inherent feature of anodic film 204 causes the dye concentration profile to persist regardless of the dye infusing process.

It is notable that, for these reasons, dye up-take can be further controlled by the anodizing process, with longer anodizing times typically resulting in faster dye up-take. Hotter or more concentrated anodizing electrolytes also result in faster dye up-take, as does a dye “activation” step (e.g., immersion in a dilute nitric acid solution immediately prior to dyeing). All of these factors are consistent with dye up-take being controlled to a large extent by surface adsorption, and with this, in turn, being controlled by the extent of chemical dissolution of the pore wall 212 structure.

In the present work, the dye concentration profile of anodic film 204 is modified by controlled removal of dye 208, which minimizes or eliminates the afore-mentioned problems.

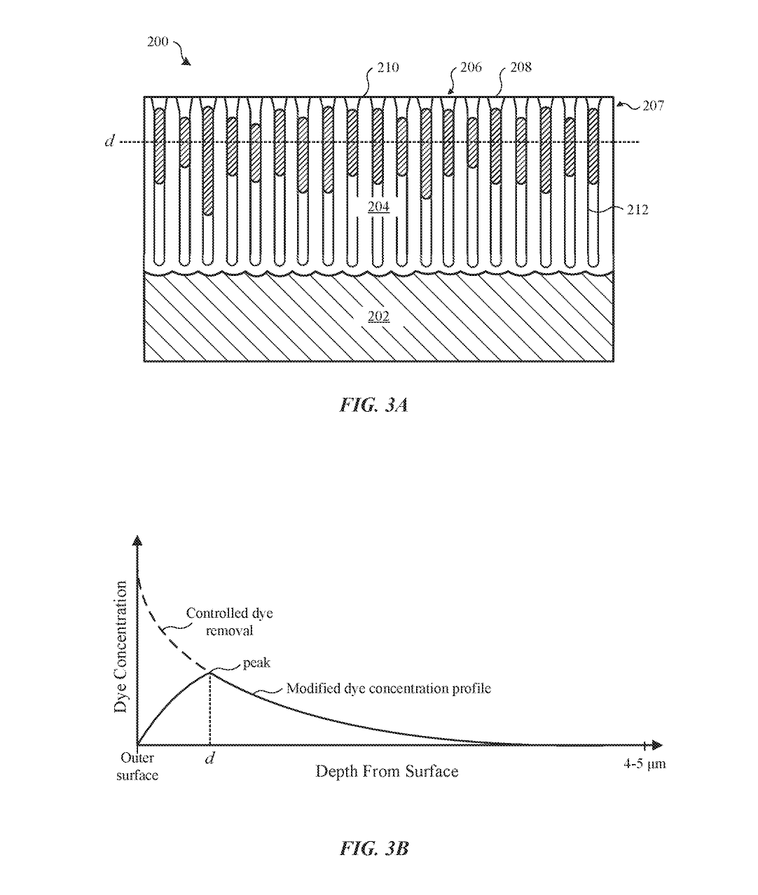

FIG. 3A shows part 200 after a controlled dye removal process, in accordance with some embodiments. The dye removal process, also referred to as a dye leaching process, involves removing at least some of dye 208 within outer portion 207 such that the peak of dye concentration shifts to depth d from outer surface 210. FIG. 3B shows a graph indicating the concentration of dye 208 within anodic film 204 as a function of depth from outer surface 210. The graph of FIG. 3B shows that controlled removal of the dye near the outer surface modifies the dye concentration profile such that the peak of dye concentration is shifted away from the outer surface to depth d (as measured from the outer surface).

This dye concentration peak shift away from outer surface 210 enables removal of dye 208 from outer portion 207 without the detrimental effects described above. For example, finishing operations, such as buffing or lapping, of outer surface 210 can be performed with less color change and less visible uneven coloring. In some embodiments, the shifted dye concentration profile can reduce the amount of dye from about 50% in the outermost half micrometer to about 25%, thereby allowing more material to be removed from the surface within the constraints of any given color shift limit.

The extent of dye removal and depth d of the peak dye concentration can be chosen based on particular application requirements. In some applications, the peak dye concentration is shifted to at least 200 nanometers from outer surface 210 of anodic film 204. That is, depth d is about 200 nanometers or greater. In some applications, the peak dye concentration should be shifted further, such as to at least 400 nanometers from outer surface 210. In some applications, the peak dye concentration should be shifted to at least 500 nanometers from outer surface 210. In some applications, the peak dye concentration is preferably between 200 nanometers and 2.5 micrometers from outer surface 210.

In some embodiments, controlled removal of dye 208 involves rinsing or immersing part 200 with a hot aqueous solution, which causes some of dye 208 to leach out of anodic film 204 by diffusive action. This process should be performed after the dyeing process, but before a sealing process used to seal pores 206. Upon exposure to the hot aqueous solution, dye 208 is desorbed from surfaces of pore walls 212 and into the aqueous solution. In some case, the aqueous solution is preferably kept below about 80 degrees Celsius since higher temperatures may cause pores 206 to hydrothermally seal by boehmite formation. In particular embodiments, a solution temperature of about 75 degrees Celsius offers rapid dye leaching without any significant sealing. In some cases, high purity de-ionized water is preferably used as a basis for the solution in order to avoid impurities such as silicon-based compounds, fluorides, phosphates and chlorides, which may inhibit sealing (in a subsequent sealing process) or corrode certain types of substrate metals. In some cases, additives are added to the solution to avoid smutting, or to promote desorption of dye 208. For example, the pH might be adjusted to a slightly acidic pH of about 5.5 using acetic acid, or to a slightly basic pH of about 8.0 using ammonium hydroxide. A polar compound, such as sodium sulfate, might also be used.

Unlike the dye adsorption, this dye removal process appears to have a strong element of diffusion control, with desorption from the outer surface 210 occurring fastest and/or first. The end result is a very significantly reduced concentration of dye 208 at outermost portion 207, whilst the concentration of dye 208 deeper into pores 206 remains unchanged. The effectiveness of this operation is a surprising result given the observed characteristics of dye uptake. As noted previously, diffusion control may play little or no role in dye up-take. Instead, dye up-take and the conventional dye concentration profile appears to be controlled by the condition of pore walls 212 at outermost portion 207.

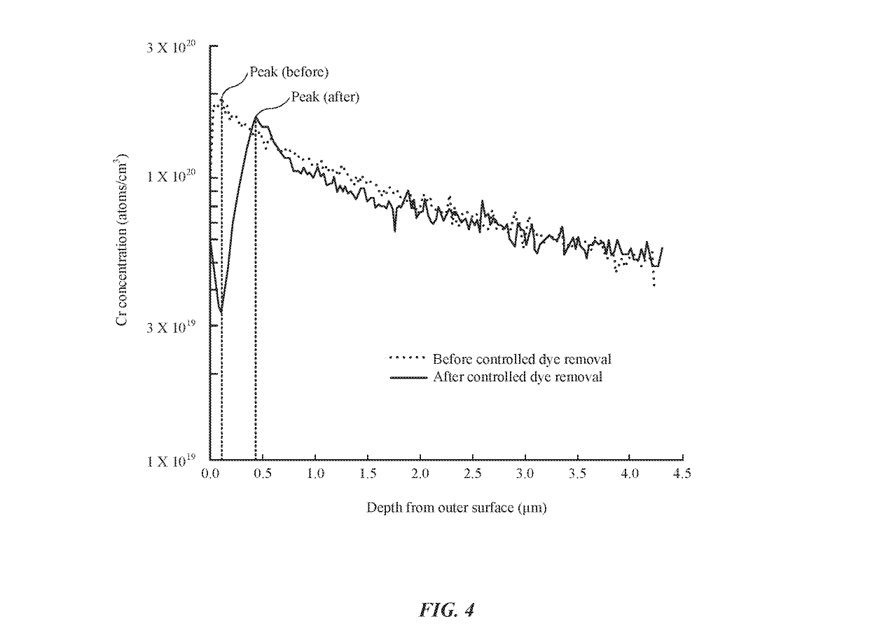

The extent of dye removal can be controlled, for example, by controlling the amount of time that part 200 is exposed to the hot aqueous solution, the temperature of the hot aqueous solution, and the method of exposure to the hot aqueous solution (e.g., rinsing or immersion). In general, exposure time and temperature of the solution affect the rate of dye leaching, with greater exposure times and higher temperatures being more efficient. In some cases, the exposure time and temperature are adjusted through empirical feedback. For example, color monitoring can occur in-situ by removing the part 200 in the middle of a leaching process for an intermediate color checkpoint, followed by time or rate adjustment for the remainder of the leaching process. The color checkpoint can include performing a chemical analysis of anodic film 204 at different depths. For example, dye 208 can include chemical agents, such as chromium, copper or sodium, which are detectable by secondary ion mass spectroscopy (SIMS) techniques. Example depth profile measurements using SIMS are described below with reference to FIG. 4.

In some cases, one or more samples can be treated for different exposure times and/or at different temperatures, and tested to determine the amount of dye removal. Once an optimal exposure time and temperature are identified, these parameters may be used during manufacturing. In a particular embodiment, an exposure time of about 10 minutes at about 75 degrees C. is found to eliminate in-service development of an iridescent surface film on certain dark black dyed surface finishes during long-term exposure to sweat or alkaline water.

After the dye removal process is complete, pores 206 of anodic film 204 are typically sealed using, for example, a hydrothermal process. A hydrothermal sealing process generally involves immersing part 200 in a hot aqueous solution at higher temperatures, i.e., about 100 degrees Celsius or higher, which causes hydration and transformation of the metal oxide material to a boehmite structure. This, in turn, causes pore walls 212 to swell and close off at outer portion 207, thereby plugging pores 206 and locking in the concentration gradient of dye 208. In addition, the sealing process increases the corrosion protection properties of anodic film 204. In some applications, anodic film 204 should have a hardness of 300 HV or greater (as measured by Vickers hardness test), in some cases 350 HV or greater.

The modified dye concentration distribution may be greatly beneficial in circumstances where dye 208 might otherwise inhibit sealing. In particular, the reduction of dye 208 at the external ends of pores 206 may allow for an increase of the integrity and robustness of the hydrothermal seal at the external ends of pores 206. In some applications, this improved sealing may also increase overall the corrosion resistance of part 200. However, in some cases this may only impact the outermost tens or hundreds of nanometers of depth, and may not ultimately have significant bearing on the net corrosion resistance of sealed, anodized part 200 (for instance, as assessed by conventional seal quality measures like admittance testing or acid dissolution testing). Nevertheless, the integrity of outer portion 207 may be critical to the long-term cosmetic performance of part 200 while in service. Specifically, having an optimal hydrothermal seal in the outermost hundreds of nanometers can eliminate or delay mechanisms of very localized surface erosion or corrosion, which would otherwise result in undesirable changes to the surface finish during extended service and environmental exposure. Such changes may include a feeling of “tackiness” and reduced stain resistance (both consequence of increased surface porosity or roughness), discoloration, development of haze, a white bloom, or an iridescent thin film. These defects may be uniform, or may be non-uniform and patchy, making them even more apparent. Darker dye colors may exacerbate thin film iridescence and the perception of haze or bloom, as well as certain types of staining.

In some embodiments the dye removal process is combined with a sealing operation. For example, a less efficient sealing operation can be implemented by sealing at a lower than conventional optimal hydrothermal sealing temperature, hence allowing a limited degree of dye leaching during sealing, prior to the outer extremities of pores 206 being sufficiently plugged to permanently seal in the dye. However, this compromise may limit the extent to which dye 206 can be leached, as it will slow and stop after a certain amount of surface sealing. Combining the dye removal and sealing processes may also reduce control of coloring, because unlike a separate leach process, the sealing process may not have in-situ color monitoring and may not be stopped for an intermediate color check-point and then time or rate adjusted. Also, the selection of a less efficient sealing processes can in itself result in defects such as in-process corrosion, or the formation of smut or bloom on the sealed surface, poorer surface plugging (with correspondingly reduced stain resistance of part 200) and a lower quality final seal.

For these reasons, it may be preferable to use a separate stage for dye leaching. However, in some cases it may be possible to keep part 200 in the same solution during both the dye leaching and sealing processes. For example, the leaching process can be performed in an aqueous solution below 80 degrees Celsius for a time period sufficient to remove some of dye 208, after which time the temperature of the solution is raised to 100 degrees Celsius or higher to seal pores 206. This arrangement can save production time, but may not be preferable in circumstances, for example, where chemical components within a leaching solution hinders adequate sealing of pores 206.

After sealing, anodic film 204 is optionally finished using, for example, a light mechanical finishing operations, such as surface buffing, which can provide a specularly reflective shine to anodic film 204. Since the peak of dye concentration is shifted deeper within anodic film 204, the finishing operation can be performed with less color shifting and with less uneven coloring compared to an anodic film in which a dye leaching process was not performed.

FIG. 4 shows a graph based on secondary ion mass spectroscopy (SIMS) data comparing dye concentration profiles of an anodized substrate before and after a controlled dye removal process. The anodic film of the anodized substrate includes a dye having chromium atoms, which are used in many black dyes and which are easily detected using SIMS. SIMS can also generate a quantitative depth profile of dye the within the anodic film, as shown in FIG. 4. The graph of FIG. 4 shows that the peak of dye concentration is around 0.1-0.2 micrometers from the outer surface (0.0 micrometers). After the dye removal process, the peak of dye concentration shifts away from the outer surface toward the interior of the anodic film—in particular, to about 0.4-0.5 micrometers from the outer surface. This shift in dye distribution has little to no effect on the appearance of the anodic film—i.e., the anodic film appeared visually the same color and measured to have a ΔE* of less than one (per CIELAB color space models) after the dye removal process relative to before the dye removal process.

It should be noted that the peak of dye concentration could be shifted to any desired depth (i.e., not limited to 0.5 micrometers), and can be chosen based on particular application requirements. Furthermore, the methods described herein are not limited to any particular type of dye or analysis techniques. For example, SIMS can be used to generate a quantitative depth profile of other chemical species, such as copper, sodium, etc. Moreover, the peak of dye concentration within an anodic film can be characterized using any suitable technique other than SIMS including, for instance, confocal Raman spectroscopy.

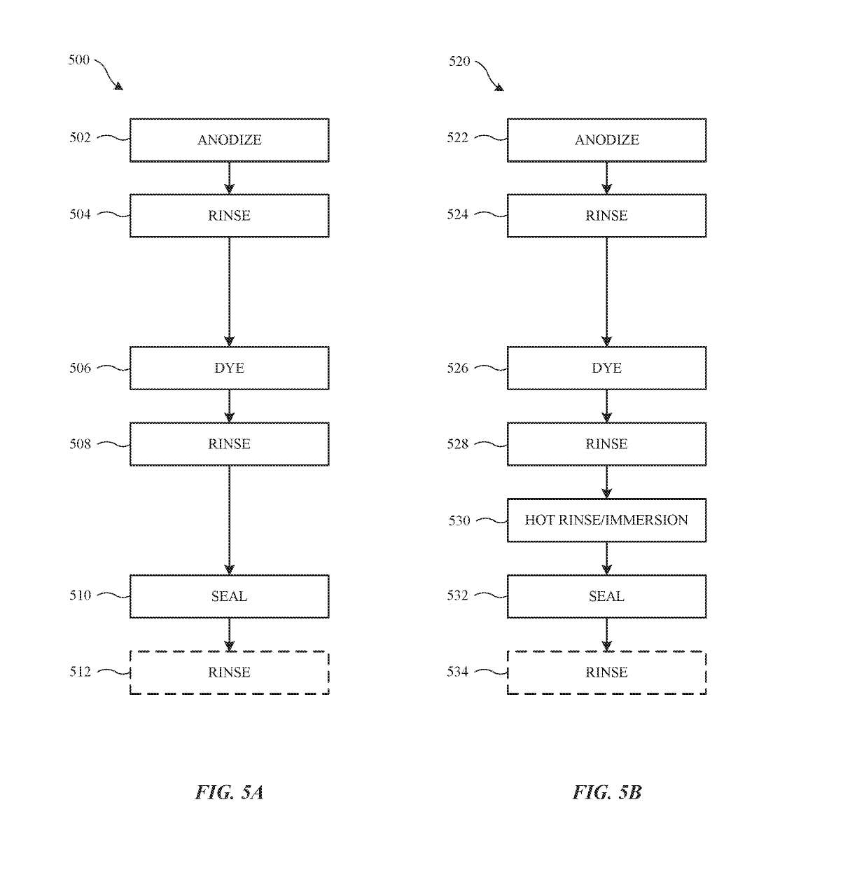

FIG. 5A shows flowchart 500 indicating a process for dyeing an anodic film without a dye leaching operation. At 502, a substrate is anodized using any suitable anodizing process. At 504, the anodized substrate is rinsed using, for example one or more of a cold water rinse and chemical rinse (e.g., desmutting). At 506, the anodic film of the anodized substrate is dyed. At 508, the dyed anodized substrate is rinsed to remove residual dye (e.g., room temperature rinse). At 510, the anodic film is sealed to close off the pores within the anodic film. At 512, the sealed anodized substrate is optionally rinsed using, for example, a cold water rinse.

FIG. 5B shows flowchart 520 indicating a process for dyeing an anodic film with a dye leaching operation, in accordance with some embodiments. At 522, a substrate is anodized using any suitable anodizing process. At 524, the anodized substrate is rinsed using, for example one or more of a cold water rinse and chemical rinse (e.g., desmutting). At 526, the anodic film of the anodized substrate is dyed. At 528, the dyed anodized substrate is rinsed to remove residual dye (e.g., room temperature rinse). At 530, dye is removed from an outer portion of the anodic film. As described above, this shifts the peak of concentration of the dye within the anodic film. At 510, the anodic film is sealed to close off the pores within the anodic film. As discussed above, the sealing operation may be improved by removing some of the dye form the outer portion of the anodic film. At 512, the sealed anodized substrate is optionally rinsed using, for example, a cold water rinse.

The foregoing description, for purposes of explanation, uses specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not intended to be exhaustive or to limit the embodiments to the precise forms disclosed. It will be apparent to one of ordinary skill in the art that many modifications and variations are possible in view of the above teachings.

What is claimed is:

1. A part, comprising:
an anodic film having a dye deposited therein, wherein a peak of concentration of the dye is at least 200 nanometers from an outer surface of the anodic film.

2. The part of claim 1, wherein the peak is between 200 nanometers and 2.5 micrometers from the outer surface of the anodic film.

3. The part of claim 1, wherein the peak is at least 500 nanometers from the outer surface of the anodic film.

4. The part of claim 1, wherein the dye includes metal ions.

5. The part of claim 1, wherein the dye includes one or more of chromium, copper and sodium.

6. The part of claim 1, wherein the anodic film is an aluminum oxide film.

7. The part of claim 1, wherein the anodic film has a hardness of 300 HV or greater.

8. The part of claim 1, wherein the dye includes a chromophore.

9. The part of claim 1, wherein pores of the anodic film are sealed.

10. A method of dyeing an anodic film, the method comprising:
depositing a dye within pores of the anodic film; and
removing some of the dye from the pores such that a peak of concentration of the dye is at least 200 nanometers from an outer surface of the anodic film.

11. The method of claim 10, wherein the peak is between 200 nanometers and 2.5 micrometers from the outer surface of the anodic film.

12. The method of claim 10, wherein removing some of the dye includes exposing the anodic film to an aqueous solution.

13. The method of claim 12, wherein the aqueous solution has a temperature no greater than about 80 degrees Celsius when removing some of the dye.

14. The method of claim 10, further comprising sealing the pores of the anodic film after removing some of the dye.

15. The method of claim 10, further comprising finishing the outer surface of the anodic film.

16. An electronic device, comprising:
an aluminum alloy substrate having an anodic film with a dye deposited therein, the anodic film characterized as having a peak of concentration of the dye that is at least 200 nanometers from an outer surface of the anodic film.

17. The electronic device of claim 16, wherein the peak is at least 500 nanometers from the outer surface of the anodic film.

18. The electronic device of claim 16, wherein the anodic film has pores with diameters ranging between about 5 nm to 100 nm.

19. The electronic device of claim 16, wherein anodic film includes a metal positioned within terminuses of the pores.

20. The electronic device of claim 16, wherein a thickness of the anodic film ranges from about 5 micrometers to about 50 micrometers.
